(19) United States
(12) Patent Application Publication
(10) Pub. No.: US 2022/0007537 A1
(43) Pub. Date: Jan. 6, 2022

(54) CONTAINER MODULE, CONTAINER ASSEMBLY, AND DATA CENTER

(71) Applicant: Huawei Technologies Co., Ltd., Shenzhen (CN)

(72) Inventors: Xiong HU, Shenzhen (CN); Wei JIAN, Shenzhen (CN); Jijun CHEN, Dongguan (CN)

(21) Appl. No.: 17/481,016

(22) Filed: Sep. 21, 2021

Related U.S. Application Data
(63) Continuation of application No. PCT/CN2020/081928, filed on Mar. 28, 2020.

(30) Foreign Application Priority Data
Jul. 19, 2019 (CN) 201910657453.4

(51) Int. Cl. H05K 7/18

(52) U.S. Cl. CPC H05K 7/183

(57) ABSTRACT

A container module includes a baseplate assembly and a plurality of columns, where the baseplate assembly includes a base frame and a baseplate fixed on the base frame, the plurality of columns are fixed on the base frame in parallel to each other, each column has an extension section extending above the baseplate assembly, and/or a lower end of each column has an extension section extending below the baseplate assembly. A container assembly includes at least two container modules that are stacked vertically and/or connected laterally. A data center includes a function device and the container module.

### CROSS-REFERENCE TO RELATED APPLICATIONS

This application is a continuation of International Application No. PCT/CN2020/081928, filed on Mar. 28, 2020, which claims priority to Chinese Patent Application No. 201910657453.4, filed on Jul. 19, 2019. The disclosures of the aforementioned applications are hereby incorporated by reference in their entireties.

### TECHNICAL FIELD

This application relates to the technical field of communication devices, and in particular, to a container module, a container assembly, and a data center.

### BACKGROUND

With the booming of industries such as the Internet, big data, cloud computing, and artificial intelligence, construction demands for data centers have shown explosive growth. A concrete structure is usually adopted in construction of a conventional data center, and has disadvantages such as a long construction cycle, poor flexibility, high costs, and inconvenient maintenance and management. Therefore, the concrete structure cannot meet the demands of the times.

As a new model of data center construction, a prefabricated data center is still under continuous exploration and improvement. Briefly, a modular design concept is adopted for the prefabricated data center, and a container is usually adopted to replace the concrete structure. Data center equipment (such as a server) can be installed in the container. Therefore, the container has obvious advantages of rapid deployment and flexible expansion, and can overcome many disadvantages of conventional civil construction modes. However, there are still many disadvantages of conventional prefabricated data centers. For example, when a large quantity of containers need to be deployed, the plurality of containers cannot be well matched, resulting in a waste of resources. In addition, because the container has a closed container structure, it is not convenient to wire and install devices in the plurality of containers.

### SUMMARY

This application provides a container module, a container assembly, and a data center that are easy to install and save materials.

In one aspect, an embodiment of this application provides a container module, including a baseplate assembly and a plurality of columns, where the baseplate assembly includes a base frame and a baseplate fixed on the base frame; the plurality of columns are fixed on the base frame in parallel to each other; and each column has an extension section extending above the baseplate assembly, and/or each column has an extension section extending below the baseplate assembly. The base frame in the baseplate assembly may provide a relatively strong stress strength to ensure overall structural strength of the baseplate assembly. The baseplate installed on the base frame may provide an installation surface required by industrial equipment or provide a flat living surface for an occupant. The industrial equipment is used as an example. The industrial equipment may be placed directly on the baseplate, or fixed to the baseplate by using a screw or a rivet, through welding, or the like, so as to improve stability of the industrial equipment and avoid position offset. Certainly, to provide an accommodating space in a vertical direction, in an embodiment provided in this application, the container module further includes a plurality of columns, and the plurality of columns may be vertically or obliquely fixed on the base frame. An upper end of each column may extend above the baseplate assembly, or a lower end of each column may extend below the baseplate assembly. Each column may have an extension section extending above the baseplate assembly, or each column may have an extension section extending below the baseplate assembly, or each column may have both an extension section extending above the baseplate assembly and an extension section extending below the baseplate assembly.

When two container modules are vertically stacked, with support of the columns, a distance between a baseplate assembly at an upper layer and a baseplate assembly at a lower layer can be maintained, so that a vertical space for accommodating industrial equipment is formed between the baseplate assembly at the upper layer and the baseplate assembly at the lower layer.

In some exemplary implementations, the container module and the baseplate assembly may have various overall outlines.

For example, the overall outline of the container module may be in a rectangular cube structure, a cylindrical structure, or a cube structure in another shape. Correspondingly, the overall outline of the baseplate assembly may be in an approximately rectangular plate-like structure, a circular plate-like structure, or another shape.

For example, the overall outline of the container module is in a rectangular cube structure. The overall outline of baseplate assembly is of an approximately rectangular plate-like structure, four columns may be arranged in the container module, and the four columns may be arranged at four corners of the baseplate assembly. Certainly, in another implementation, there may be more columns, and the columns may alternatively be arranged at side edges or in other positions of the baseplate assembly.

The baseplate assembly may have various structure forms.

For example, in an embodiment provided in this application, the base frame may include two trusses arranged in parallel to each other. The two trusses are arranged laterally, and the baseplate is fixed on upper sides or lower sides of the two trusses. The two trusses being arranged laterally may be understood as a length direction of the trusses being parallel to a horizontal plane, or a length direction of the trusses being parallel to a plate surface of the baseplate.

A truss refers to a planar or spatial structure that has a triangular or trapezoidal unit and that includes a pole assembly, and has advantages of saving materials and reducing a structural weight. In an embodiment provided in this application, the truss includes a top chord and a bottom chord that are arranged in parallel, and a plurality of truss webs are connected between the top chord and the bottom chord. The truss webs may be vertically connected to the top chord and the bottom chord, or the truss webs may be connected to the top chord and the bottom chord at an inclination angle. The truss webs, the top chord, and the bottom chord are connected to form a plurality of triangular outlines. Such structure arrangement can effectively improve stress performance of the truss, and has advantages of reduced material consumption, a light weight, and the like.

Certainly, to improve structural strength and integrity of the base frame, in some implementations, the two trusses may further be connected.

For example, in an embodiment provided in this application, the two trusses are connected by using a plurality of lower short beams. Specifically, two ends of each lower short beam are respectively connected to two top chords, and each lower short beam is arranged perpendicular to the top chords. Certainly, in another implementation, two ends of each lower short beam may alternatively be respectively connected to two bottom chords, or there are both a lower short beam connected to two top chords and a lower short beam connected to two bottom chords. Certainly, in some exemplary implementations, the lower short beam may alternatively be connected to two top chords at an inclination angle.

In addition, the two trusses may alternatively be connected by using the baseplate.

In an embodiment provided in this application, the baseplate is arranged on an upper side of the base frame and is fixedly connected to the two trusses. Certainly, in another implementation, the baseplate may alternatively be arranged on a lower side of the base frame, the baseplate may be arranged in the middle of the two trusses, or the like.

Certainly, in some exemplary implementations, to improve connection strength between the baseplate and the base frame and to avoid affecting connection stability between the baseplate and the base frame due to thermal expansion and contraction, the baseplate may be spliced by a plurality of baseplate units.

In addition, to facilitate vertical splicing of a plurality of container modules, in some exemplary implementations, a first connecting portion may be arranged at the top of the column, and a second connecting portion may be arranged at the bottom of the column. In an exemplary embodiment, when two container modules are vertically stacked, a second connecting portion at the bottom of a column of the container module at the upper layer may be connected to a first connecting portion at the top of a column of the container module at the lower layer.

A connection manner between the container module at the upper layer and the container module at the lower layer may be welding, screwing, riveting, clamping, or the like.

Because the container module may be directly used in an outdoor environment when actually being used, to improve tightness of the container module or an entire container assembly, a side panel structure may be further arranged on a side surface of the container module or a side surface of the container assembly.

A side panel may be pre-installed in the container module or may be finally installed on an outer side of the container assembly.

The container assembly or the container module may meet various use requirements.

For example, the container assembly or the container module may be used as a house for people to live in, or used as a factory building or a warehouse for accommodating industrial equipment.

An embodiment of this application further provides a data center, including a function device and any one of the foregoing container assemblies. The function device may include a server, a heat dissipation device, a power generation device, and the like. An appropriate stacking manner may be selected for a plurality of container modules based on an installation requirement of the data center, thereby having relatively high construction flexibility.

### BRIEF DESCRIPTION OF DRAWINGS

FIG. 1 is an application scenario diagram of a container module according to an embodiment of this application;

FIG. 2 is another application scenario diagram of a container module according to an embodiment of this application;

FIG. 3 is a schematic structural diagram of a container module according to an embodiment of this application;

FIG. 4 is a schematic structural diagram of a base frame according to an embodiment of this application;

FIG. 5 is a partially enlarged view of FIG. 4;

FIG. 6 is a schematic structural diagram of a truss web according to an embodiment of this application;

FIG. 7 is a schematic structural diagram of another base frame according to an embodiment of this application;

FIG. 8 is a partially enlarged view of FIG. 7;

FIG. 9 is a cross-sectional view of a lower short beam according to an embodiment of this application;

FIG. 10 is a schematic structural diagram of a baseplate assembly according to an embodiment of this application;

FIG. 11 is a schematic structural diagram of another baseplate assembly according to an embodiment of this application;

FIG. 12 is a schematic structural diagram of a container module according to an embodiment of this application;

FIG. 13 is a partially enlarged view of FIG. 12;

FIG. 14 is a schematic structural diagram of a column according to an embodiment of this application;

FIG. 15 is a composite schematic structural diagram of a container module according to an embodiment of this application;

FIG. 16 is a composite schematic structural diagram of another container module according to an embodiment of this application;

FIG. 17 is a partially enlarged view of FIG. 16;

FIG. 18 is a schematic structural diagram of another container module according to an embodiment of this application;

FIG. 19 is a schematic structural diagram of still another container module according to an embodiment of this application;

FIG. 20 is a schematic structural diagram of a side panel according to an embodiment of this application;

FIG. 21 is a schematic structural diagram of a container assembly according to an embodiment of this application;

FIG. 22 is a schematic structural diagram of another container assembly according to an embodiment of this application; and

FIG. 23 is a schematic structural diagram of a data center according to an embodiment of this application.

### DESCRIPTION OF EMBODIMENTS

To make objectives, technical solutions, and advantages of this application clearer, the following further describes exemplary embodiments of this application in detail with reference to the accompanying drawings.

Terms used in the following embodiments are only for a purpose of describing particular embodiments and are not intended for limiting this application. As used in this specification and appended claims of this application, the singular expressions “a”, “a”, “the above”, “the” and “this” are intended to also include expressions such as “one or more”, unless the contrary is clearly indicated in its context. It should be further understood that in the following embodiments of this application, “at least one” and “one or more” refer to one, two, or more. The term “and/or” is used to describe an association relationship of an associated object, and indicates that there may be three relationships. For example, A and/or B may represent a case in which only A exists, both A and B exist, and only B exists, where A and B may be singular or plural. The character “/” generally indicates an “or” relationship between the associated objects.

Reference to “one embodiment” or “some embodiments” described in this specification or the like means that one or more embodiments of this application include a particular feature, structure, or characteristic described in combination with the embodiment. Thus, phrases “in one embodiment”, “in some embodiments”, “in some other embodiments”, “in some additional embodiments”, and the like that appear in different parts in this specification do not necessarily mean referring to a same embodiment, but mean “one or more embodiments, but not all embodiments”, unless otherwise specifically emphasized. Terms “include”, “have”, and variations thereof all mean “including but not limited to”, unless otherwise specifically emphasized.

For ease of understanding a container module provided in an embodiment of this application, an application scenario of the container module is first described as follows.

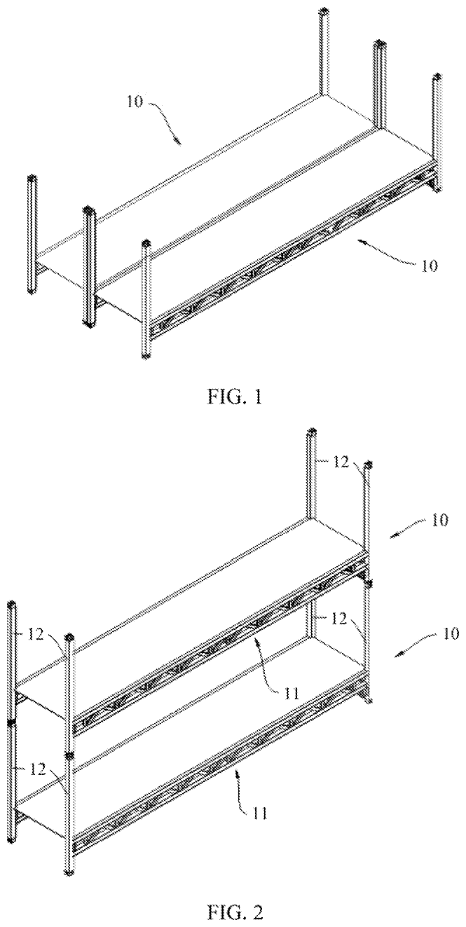

The container module in the embodiment of this application may be directly used in an outdoor environment, used to replace a conventional civil structure or used in combination with a conventional civil structure, and may be used as a house for people to live in, or used as a factory building, a warehouse, or the like for accommodating industrial equipment. In a practical application, a use quantity and position arrangements of container modules may be properly adjusted based on different requirements. For example, as shown in FIG. 1, when a relatively large lateral area is required, a plurality of container modules 10 may be arranged laterally, and the plurality of container modules 10 (only two of which are shown in the figure) may be spliced to each other to form a relatively large accommodating area. Specifically, when the industrial equipment is relatively large in volume or relatively long in length, the plurality of container modules 10 may be arranged laterally to form an accommodating space that has a relatively large lateral space, thereby satisfying an installation requirement of the industrial equipment. Certainly, as shown in FIG. 2, in some cases, the plurality of container modules 10 (only two of which are shown in the figure) may alternatively be stacked vertically to use a land area, or to satisfy different requirements of the industrial equipment. It may be understood that a quantity of container modules 10 stacked vertically and a quantity of container modules 10 arranged laterally may be two, three, or more.

The container module 10 provided in the embodiment of this application can effectively ensure structural strength and a use function of the container module 10, and has an advantage of reducing material consumption.

As shown in FIG. 3, in an embodiment provided in this application, the container module 10 includes a baseplate assembly 11 and a plurality of columns 12; the baseplate assembly 11 includes a base frame 111 and a baseplate 112 fixed to the base frame 111; the plurality of columns 12 are fixed on the base frame 111 in parallel to each other, and the plurality of columns 12 are arranged perpendicular or substantially perpendicular to the base frame 111; and each column 12 has an extension section extending above the baseplate assembly 11, and/or each column 12 has an extension section extending below the baseplate assembly 11.

Specifically, the base frame 111 in the baseplate assembly 11 may provide relatively strong stress strength to ensure overall structural strength of the baseplate assembly 11. The baseplate 112 installed on the base frame 111 may provide an installation surface required by the industrial equipment or provide a flat living surface for an occupant. The industrial equipment is used as an example. The industrial equipment may be placed directly on the baseplate 112, or fixed to the baseplate by using a screw or a rivet, through welding, or the like, so as to improve stability of the industrial equipment and avoid position offset. Certainly, to provide an accommodating space in a vertical direction, in an embodiment provided in this application, the container module 10 further includes a plurality of columns 12, and the plurality of columns 12 may be vertically or obliquely fixed on the base frame 111. An upper end of each column 12 may extend above the baseplate assembly 11, or a lower end of each column 12 may extend below the baseplate assembly 11. Specifically, as shown in FIG. 2, when two container modules 10 are stacked vertically, with support of the columns 12, a distance between the baseplate assembly 11 at the upper layer and the baseplate assembly 11 at the lower layer can be maintained, so that a vertical space for accommodating the industrial equipment is formed between the baseplate assembly 11 at the upper layer and the baseplate assembly 11 at the lower layer.

By using the foregoing structural arrangement, open arrangements of an upper part and a side part of the container module 10 can be implemented, thereby improving convenience of installing the industrial equipment 20. In addition, when a plurality of container modules 10 are arranged laterally, a connection operation is also conveniently performed on an adjacent container module 10, and a thorough lateral space can be formed, facilitating placement of industrial equipment with a relatively long length. When the plurality of container modules 10 are stacked vertically, a baseplate assembly 11 of a container module 10 at an upper layer may be used as a top cover of a container module 10 at a lower layer, so that the baseplate assembly 11 of the container module 10 at the upper layer can be used for a plurality of purposes. In addition, material consumption, manufacturing costs, transportation costs, and the like can be reduced.

The container module 10 may have various overall structures, and each component part may have various structures.

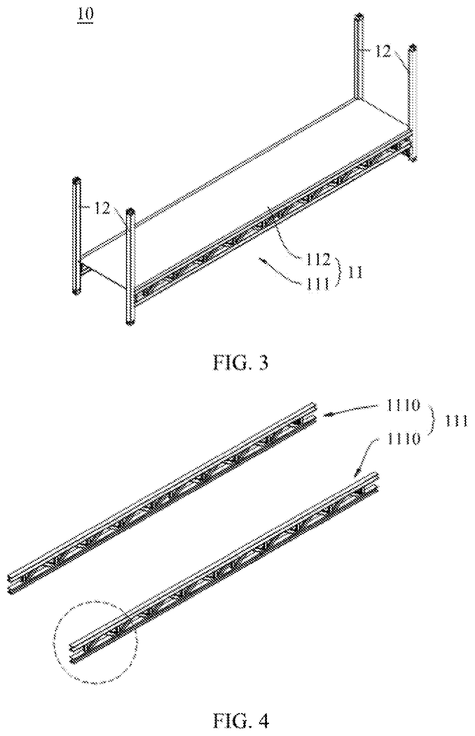

For example, as shown in FIG. 4, in an embodiment provided in this application, the base frame 111 may include two trusses 1110 arranged in parallel to each other.

Specifically, the truss 1110 refers to a planar or spatial structure that has a triangular or trapezoidal unit and that includes a pole assembly, and has advantages of saving materials and reducing a structural weight. As shown in FIG. 5, in an embodiment provided in this application, the truss 1110 includes a top chord 1111 and a bottom chord 1112 that are arranged in parallel, and a plurality of truss webs 1113 are connected between the top chord 1111 and the bottom chord 1112. Specifically, a truss web 1113a is vertically connected to the top chord 1111 and the bottom chord 1112, and a truss web 1113b is connected to the top chord 1111 and the bottom chord 1112 at an inclination angle. The truss web 1113a, the truss web 1113b, the top chord 1111, and the bottom chord 1112 are connected to form a plurality of triangular outlines. Such structure arrangement can effectively improve stress performance of the truss 1110, and has advantages of reduced material consumption, a light weight, and the like.

The top chord 1111 and the bottom chord 1112 may use an I-beam structure so that the top chord 1111 and the bottom chord 1112 themselves have relatively strong structural strength and improved tensile strength and flexural strength. Certainly, in another implementation, the top chord 1111 and the bottom chord 1112 may alternatively take a form of a T-beam structure or another structure form. In addition, three, four, or more top chord 1111 and bottom chord 1112 may be arranged in parallel or obliquely in each truss 1110 to improve overall structural strength.

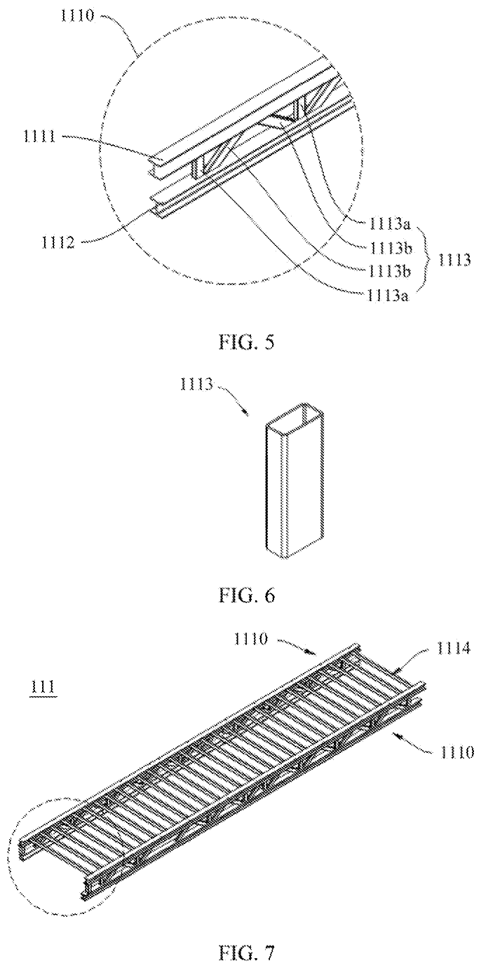

In addition, the truss web 1113 may have various structure forms. For example, as shown in FIG. 6, in an embodiment provided in this application, the truss web 1113 may use a hollow tube structure, so that the truss web 1113 has relatively strong stress performance and has an advantage of a light weight. In some specific implementations, a cross-sectional shape of the truss web 1113 may be circular (that is, the truss web is a circular tube), rectangular (that is, the truss web is a rectangular tube), or another polygonal structure. In addition, the truss web may alternatively have an I-beam structure, a T-beam structure, or the like.

The truss web 1113 and both of the top chord 1111 and the bottom chord 1112 may have various connection manners. For example, the truss web 1113 and both of the top chord 1111 and the bottom chord 1112 may be connected through welding, bolting, riveting, and the like.

In an embodiment provided in this application, the base frame 111 includes two trusses 1110 arranged in parallel to each other. To improve structural strength and integrity of the base frame 111, in some implementations, the two trusses 1110 may alternatively be connected.

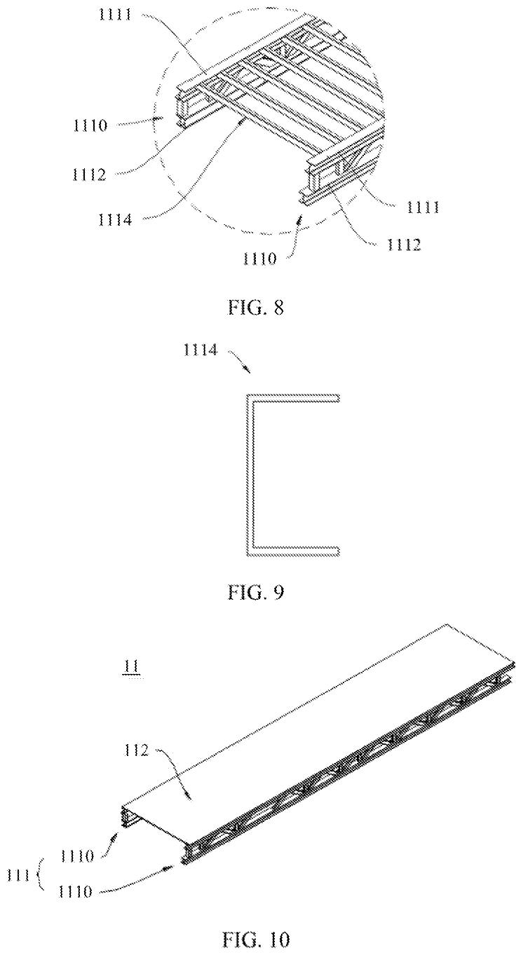

As shown in FIG. 7, in an embodiment provided in this application, the two trusses 1110 are connected by using a plurality of lower short beams 1114. Specifically, as shown in FIG. 8, two ends of each lower short beam 1114 are respectively connected to two top chords 1111, and each lower short beam 1114 is arranged perpendicular to the top chords 1111. Certainly, in another implementation, two ends of each lower short beam 1114 may alternatively be respectively connected to two bottom chords 1112, or there are both a lower short beam 1114 connected to two top chords 1111 and a lower short beam 1114 connected to two bottom chords 1112. Certainly, in some specific implementations, the lower short beam 1114 may alternatively be connected to two top chords 1111 at an inclination angle. The lower short beam 1114 may also have various structure forms. For example, as shown in FIG. 9, in an embodiment provided in this application, the lower short beam 1114 has a U-beam structure. Certainly, in another implementation, the lower short beam 1114 may alternatively have an I-beam structure, a T-beam structure, or the like.

In addition, the two trusses 1110 may alternatively be connected by using the baseplate.

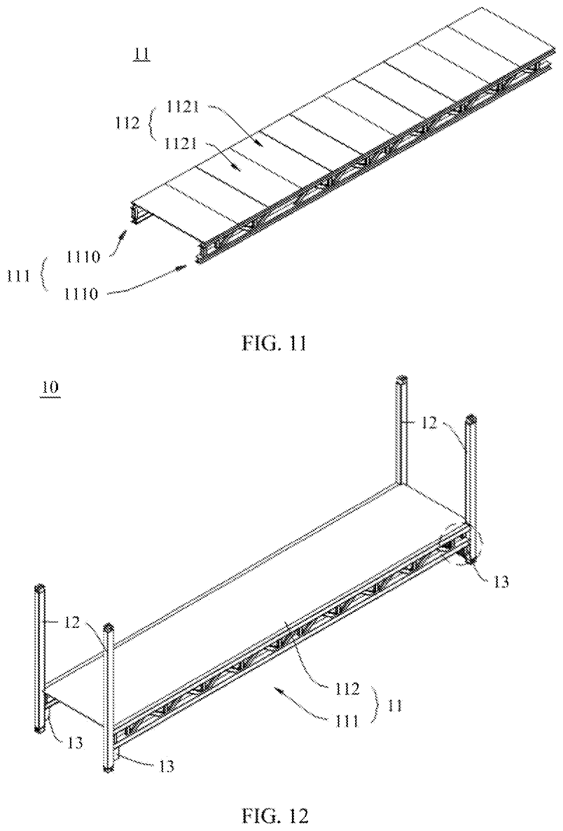

Specifically, as shown in FIG. 10, in an embodiment provided in this application, the baseplate 112 is arranged on an upper side of the base frame 111 and is fixedly connected to the two trusses 1110. Certainly, in another implementation, the baseplate 112 may alternatively be arranged on a lower side of the base frame 111, the baseplate 112 may be arranged in the middle of the two trusses 1110, or the like.

Certainly, in some specific implementations, to improve connection strength between the baseplate 112 and the base frame 111 and to avoid affecting connection stability between the baseplate 112 and the base frame 111 due to thermal expansion and contraction, the baseplate 112 may be spliced by a plurality of baseplate units 1121.

Specifically, as shown in FIG. 11, in an embodiment provided in this application, the baseplate 112 includes a plurality of separate baseplate units 1121, and each baseplate unit 1121 is fixed on the base frame 111.

Each baseplate unit 1121 may be fixedly connected to the truss 1110, may be fixedly connected to the lower short beam (not shown in the figure), or may be fixedly connected to both the truss 1110 and the lower short beam.

Certainly, in some implementations, the baseplate 112 or the baseplate unit 1121 may have a flat plate-like structure, or may have a corrugated or another plate-like structure.

In addition, the baseplate 112 or the baseplate assembly 11 may have various overall structures.

For example, as shown in FIG. 11, in an embodiment provided in this application, the baseplate 112 as a whole has a rectangular structure. Certainly, in another implementation, the baseplate 112 as a whole may alternatively have a polygonal structure such as a disk or a triangle. Correspondingly, a use quantity of columns 12 and relative positions between the columns 12 and the baseplate assembly 11 may be variously adjusted.

As shown in FIG. 12, in an embodiment provided in this application, the baseplate assembly 11 (or the baseplate 112) as a whole has a rectangular structure, and there are four columns 12, respectively fixed at four corners of the baseplate assembly 11.

The column 12 may be fixedly connected to the base frame 111 through welding, by using a screw or a rivet, or the like.

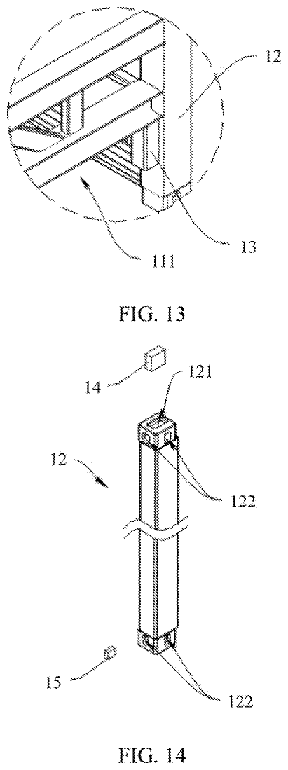

For example, in an embodiment provided in this application, the column 12 may be fixedly connected to the base frame 111 through welding. Specifically, a side part of the column 12 is welded to an end part of the base frame. Certainly, to improve connection convenience and structural stability between the column 12 and the base frame 111, as shown in FIG. 13, a positioning block 13 may be arranged at a side part of the column 12. When the column 12 and the base frame 111 need to be connected, the base frame 111 may be first lapped on the positioning block 13 to improve positioning accuracy between the column 12 and the base frame 111, and then the column 12 and the base frame 111 may be fixedly connected through welding. It may be understood that because the base frame 111 is lapped on the positioning block 13, the positioning block 13 may further provide some support for the base frame 111 to increase a load capacity of the base frame 111 (or the baseplate assembly 11).

In addition, in consideration that when a plurality container modules 10 are stacked vertically, a lower end of a column 12 of a container module 10 at an upper layer needs to be connected to a upper end of a column 12 of a container module 10 at an lower layer, a lower end of a column 12 may extend slightly below the baseplate assembly 11 to improve connection convenience. For example, when the column 12 at the upper layer is welded to the column 12 at the lower layer in a manner of welding, an operation space is required. Therefore, the lower end of the column 12 may extend slightly below the baseplate assembly 11 to form an operation space, thereby facilitating a welding operation by an operator.

To facilitate precise interconnection between the column 12 of the container module 10 at the upper layer and the column 12 of the container module 10 at the lower layer, in some specific implementations, a positioning structure may be arranged at both of an upper end and a lower end of the column 12.

For example, as shown in FIG. 14, in an embodiment provided in this application, the upper end of the column 12 has a positioning hole 121 that opens upwardly, and the lower end of the column 12 has a positioning hole (not shown in the figure) that opens downwardly. When container modules 10 are stacked vertically, an auxiliary positioning structure 14 may be first inserted into a positioning hole 121 of a container module 10 at a lower layer, and then the auxiliary positioning structure 14 is inserted into a positioning hole of a container module 10 at an upper layer, thereby implementing precise interconnection between the two container modules 10 at the upper layer and at the lower layer. Certainly, in some implementations, the upper end or the lower end of the column 12 may alternatively be formed with a structure of the auxiliary positioning structure 14, to facilitate insertion into the positioning hole at the lower end or the upper end of the column 12, thereby implementing precise interconnection.

In addition, when a plurality of container modules 10 are spliced laterally, to improve interconnection precision between two adjacent container modules 10, in some specific implementations, the side part of the columns 12 may further be provided with a positioning structure.

For example, as shown in FIG. 14, in an embodiment provided in this application, the side part of the column 12 has a positioning hole 122 arranged laterally. When two container modules 10 are interconnected laterally, an auxiliary positioning structure 15 may be first inserted into a positioning hole 122 of one container module 10, and then the auxiliary positioning structure 15 is inserted into a positioning hole 122 of the other container module 10, thereby implementing lateral precise interconnection between the two container modules 10. Certainly, in some implementations, the side part of the column 12 may alternatively be formed with a protruding auxiliary positioning structure to precisely interconnect with a positioning hole 122.

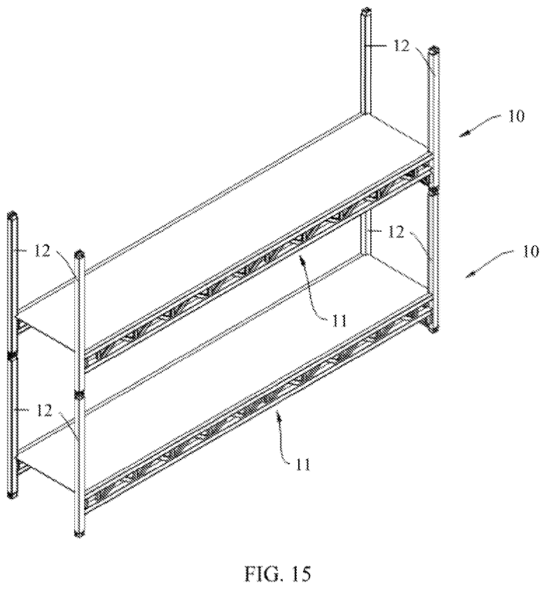

As shown in FIG. 15, two adjacent container modules 10 may be fixedly connected through welding or by using an auxiliary connecting structure.

For example, in an embodiment provided in this application, after a container module 10 at an upper layer and a container module 10 at a lower layer are interconnected, a lower end of a column 12 of the container module 10 at the upper layer may be welded to an upper end of a column 12 of the container module 10 at the lower layer.

Certainly, in some specific implementations, the container module at the upper layer and the container module at the lower layer may alternatively be connected by using an auxiliary connecting structure such as a bolt or a rivet.

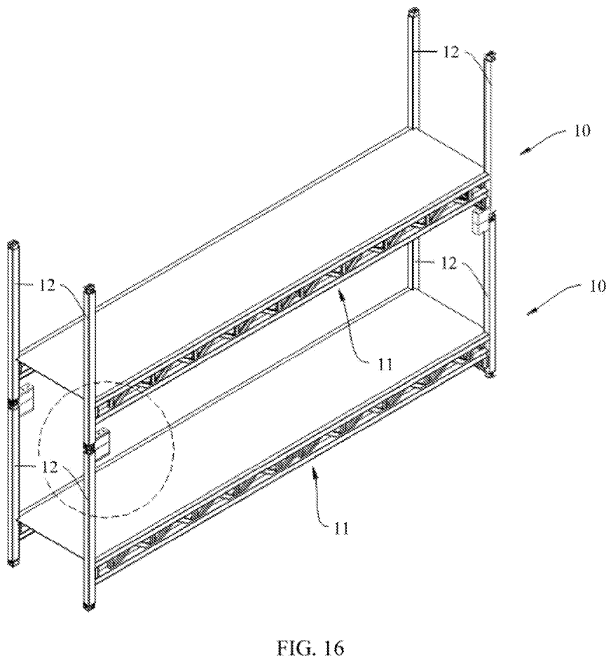

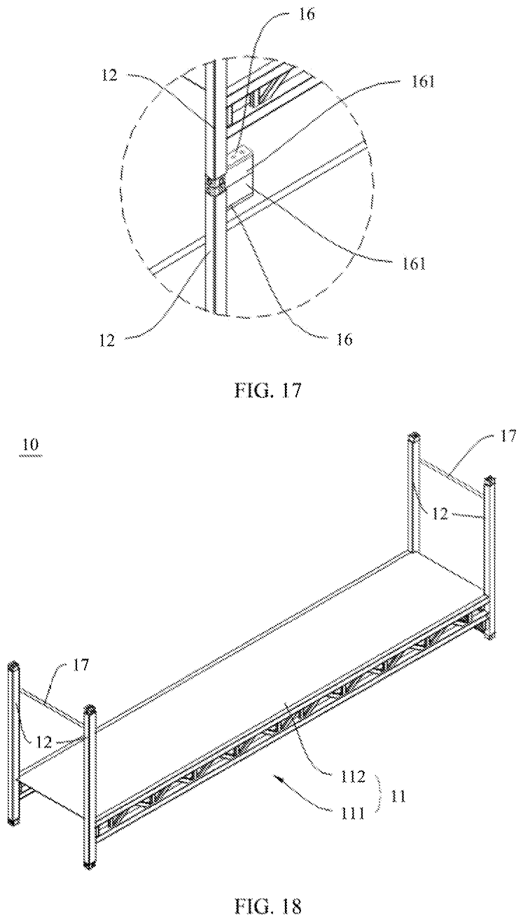

As shown in FIG. 16, in an embodiment provided in this application, the container module at the upper layer and the container module at the lower layer are connected by using bolts. Specifically, as shown in FIG. 17, a connecting plate 16 is arranged near both an upper end and a lower end of a column 12, and the connecting plate 16 is provided with a through-hole for a bolt to penetrate. After the container module 10 at the upper layer and the container module 10 at the lower layer are interconnected, a bolt (not shown in the figure) may be used to penetrate through through-holes of two upper and lower connecting plates 16 and match with a nut to connect the two connecting plates 16, thereby implementing connection of the two container modules 10. Certainly, in some specific implementations, to improve connection strength between the connecting plate 16 and the column 12, a reinforcing plate 161 may be further arranged between the connecting plate 16 and the column 12 to prevent the connecting plate 16 from being bent and deformed, thereby effectively improving connection stability between two adjacent container modules 10.

It may be understood that when a plurality of container modules 10 are interconnected laterally, they may alternatively be fixedly connected through welding or by using an auxiliary connecting structure. Certainly, when two adjacent container modules 10 are connected by using a bolt, the two container modules 10 may alternatively be fixedly connected by arranging the connecting plate 16. It may be understood that the connecting plate 16 may be arranged in various positions.

An upper end of a column 12 may extend above the baseplate assembly 11 by various lengths. Correspondingly, a lower end of a column 12 may also extend below the baseplate assembly 11 by various lengths. Certainly, for ease of use, upper ends of all columns 12 may be kept flush, and lower ends of all the column 12 may also be kept flush, that is, all the columns 12 may extend above the baseplate assembly 11 by a same or approximately same length, and all the columns 12 may extend below the baseplate assembly 11 by a same or approximately same length.

As shown in FIG. 18, in an embodiment provided in this application, the upper end of the column 12 extends above the baseplate assembly 11 by a relatively long length. To improve stress performance of the column 12 and prevent the column 12 from being bent and deformed, in some specific implementations, an upper short beam 17 may be further arranged. Specifically, two ends of the upper short beam 17 may be connected to upper parts of two adjacent columns 12. Certainly, in another embodiment, two ends of the upper short beam 17 may alternatively be connected to the middle or other parts of two adjacent columns 12, or a plurality of upper short beams 17 may be arranged between two adjacent columns 12.

In practical application, a side panel may further be arranged to ensure tightness of the container module 10.

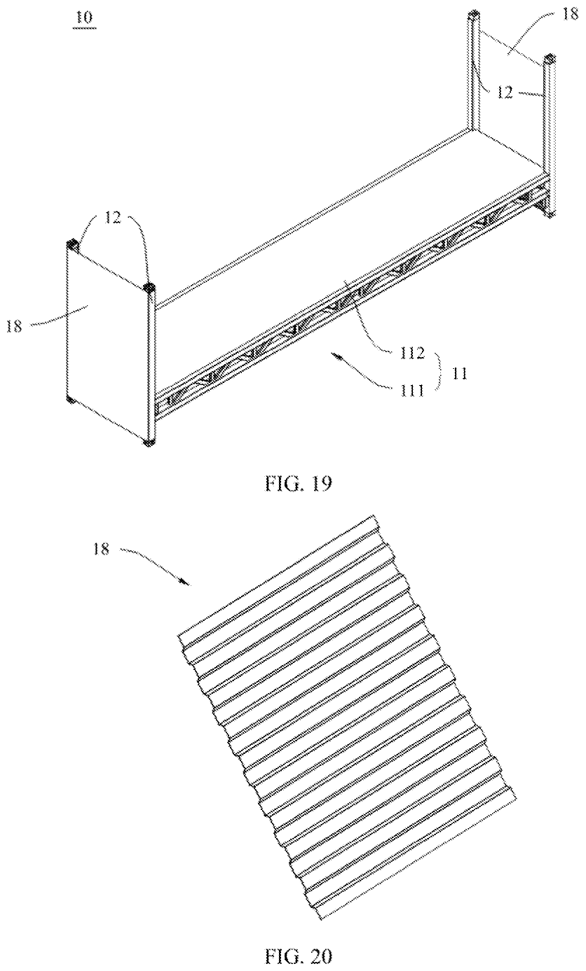

Specifically, as shown in FIG. 19, in an embodiment provided in this application, two opposite side surfaces of the container module 10 are each provided with a side panel 18. Certainly, in another embodiment, a side panel 18 may alternatively be arranged on each side surface or at least one side surface of the container module 10.

The side panel 18 may have various structure forms.

For example, as shown in FIG. 20, in an embodiment provided in this application, the side panel 18 uses a corrugated structure to have relatively good stress performance. Certainly, in another implementation, the side panel 18 may alternatively have a flat plate-like structure or a structure of another shape. In addition, structures such as a door and a window may be arranged in the side panel 18 to facilitate access of personnel and transportation of devices.

In specific application, the side panel 18 may be pre-arranged in the container module 10, or may be arranged based on actual conditions after a plurality of container modules 10 are interconnected.

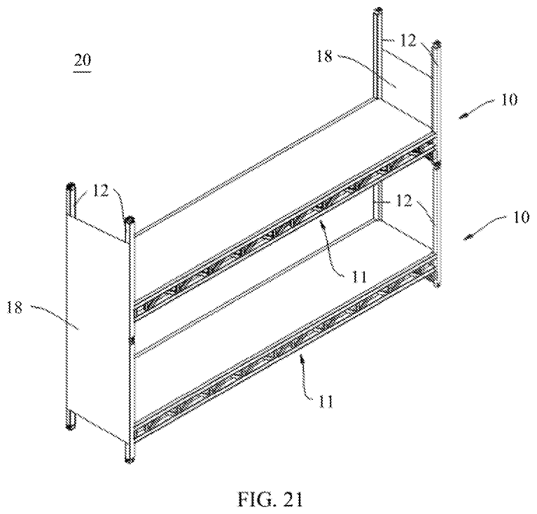

For example, as shown in FIG. 21, a container assembly 20 provided in an embodiment of this application includes a plurality of container modules 10 (two of which are shown in the figure) stacked vertically, and after the plurality of container modules 10 are stacked and fixed, the side panel 18 may be arranged on a side surface that needs to be sealed.

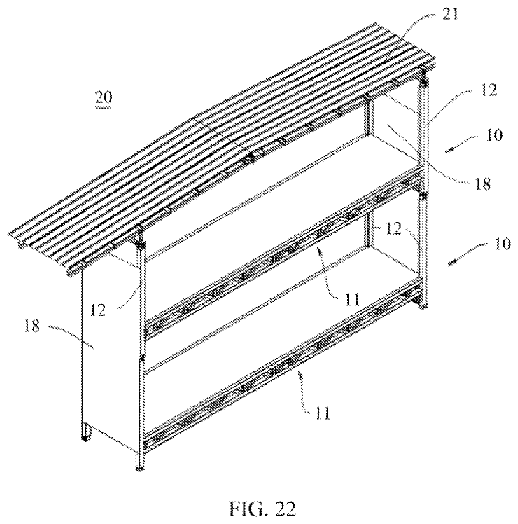

Certainly, because the container assembly 10 is directly exposed to an external environment in actual use, to implement a function such as rain-proofing, as shown in FIG. 22, a top cover structure 21 may further be arranged at the top of an uppermost container module 10 after the plurality of container modules 10 are stacked.

The top cover structure 21 may be welded to a column 12 of the uppermost container module 10. Certainly, the top cover structure 21 may be fixedly connected to the container module 10 by using a connecting structure such as a bolt or a rivet.

Certainly, in practical application, the container assembly 20 may alternatively be installed with various auxiliary structures based on actual requirements.

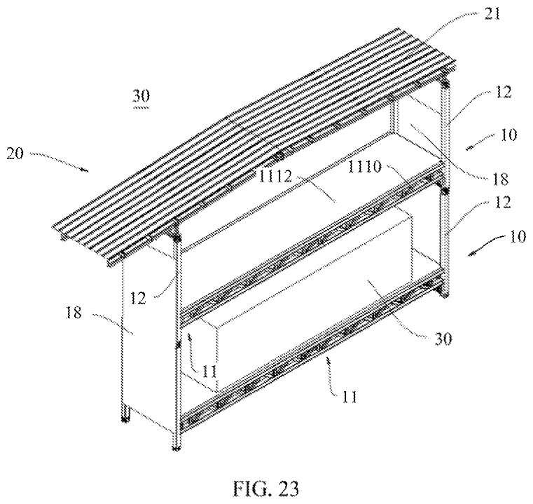

For example, as shown in FIG. 23, in a data center provided in an embodiment of this application, a plurality of server cabinets 30 are installed inside the container assembly 20. In practical application, the server cabinets 30 need to be connected to external devices through various connection cables to implement transmission of electric energy and electrical signals. Therefore, a cable tray for supporting a cable may be installed in the container assembly 20.

Specifically, the cable tray may be installed at the bottom of a container module 10 at an upper layer. Specifically, the cable tray may be connected to the truss 1110 or the baseplate 112 through welding, screwing, riveting, or the like.

The foregoing descriptions merely describe exemplary implementations of this application, and are not intended to limit the protection scope of this application. Any variation or replacement readily figured out by a person skilled in the art within the technical scope disclosed in this application may fall within the protection scope of this application. The protection scope of this application shall be subject to the protection scope of the claims.

What is claimed is:

1. A container module, comprising:
a baseplate assembly, wherein the baseplate assembly comprises a base frame and a baseplate fixed on the base frame; and
a plurality of columns fixed on the base frame, wherein the plurality of columns are parallel to each other, and wherein each column has at least one of an extension section extending above the baseplate assembly or an extension section extending below the baseplate assembly.

2. The container module according to claim 1, wherein the base frame comprises two trusses, wherein the two trusses are arranged laterally and are parallel to each other, and wherein the baseplate is fixed on upper sides or lower sides of the two trusses.

3. The container module according to claim 2, wherein the plurality of columns include four columns, and wherein two ends of each truss are each provided with a respective column of the four columns.

4. The container module according to claim 3, wherein the baseplate assembly further comprises a plurality of lower short beams, wherein two ends of each lower short beam are respectively connected to the two trusses.

5. The container module according to claim 2, wherein the baseplate assembly further comprises a plurality of lower short beams, wherein two ends of each lower short beam are respectively connected to the two trusses.

6. The container module according to claim 1, further comprising:
a plurality of upper short beams, wherein two ends of each of the plurality of upper short beams are respectively connected to two adjacent columns.

7. The container module according to claim 1, wherein upper ends of the plurality of columns are flush with each other, and lower ends of the plurality of columns are flush with each other.

8. The container module according to claim 1, wherein upper ends of the plurality of columns are flush with each other, or lower ends of the plurality of columns are flush with each other.

9. The container module according to claim 1, further comprising:
a side panel, wherein the side panel is arranged at least on one side surface of a polygonal outline defined by the plurality of columns.

10. A container assembly, comprising:
at least two container modules that are stacked vertically or that are connected laterally, wherein each of the at least two container modules comprises a baseplate assembly and a plurality of columns;
wherein the baseplate assembly comprises a base frame and a baseplate fixed on the base frame;
wherein the plurality of columns are fixed on the base frame and are parallel to each other; and
wherein each column has at least one of an extension section extending above the baseplate assembly or an extension section extending below the baseplate assembly.

11. The container assembly according to claim 10, wherein the at least two container modules are stacked vertically; and
wherein in two vertically adjacent container modules, an upper end of a column in a container module at a lower layer has a first connecting portion, a lower end of a column in a container module at an upper layer has a second connecting portion, and the first connecting portion is connected to the second connecting portion.

12. The container assembly according to claim 11, wherein a connection manner between the first connecting portion and the second connecting portion is at least one of welding, screwing, riveting, or clamping.

13. A container assembly, comprising:
at least two container modules that are stacked vertically; and
at least two container modules that are connected laterally;
wherein each of the at least two container modules that are stacked vertically and each of the at least two container modules that are connected laterally comprise a baseplate assembly and a plurality of columns;
wherein the baseplate assembly comprises a base frame and a baseplate fixed on the base frame;
wherein the plurality of columns are fixed on the base frame and are parallel to each other; and
wherein each column has at least one of an extension section extending above the baseplate assembly or an extension section extending below the baseplate assembly.

14. The container assembly according to claim 13, wherein in two vertically adjacent container modules, an upper end of a column in a container module at a lower layer has a first connecting portion, a lower end of a column in a container module at an upper layer has a second connecting portion, and the first connecting portion is connected to the second connecting portion.

15. The container assembly according to claim 14, wherein a connection manner between the first connecting portion and the second connecting portion is at least one of welding, screwing, riveting, or clamping.

16. A data center, comprising:
a function device; and
a container module;
wherein the container module comprises a baseplate assembly and a plurality of columns, wherein the baseplate assembly comprises a base frame and a baseplate fixed on the base frame, wherein the plurality of columns are fixed on the base frame and are parallel to each other, and wherein each column has at least one of an extension section extending above the baseplate assembly or an extension section extending below the baseplate assembly; and
wherein the function device is installed on the baseplate.

17. The data center according to claim 16, wherein the base frame comprises two trusses arranged laterally and parallel to each other, and wherein the baseplate is fixed on upper sides or lower sides of the two trusses.

18. The data center according to claim 17, wherein the plurality of columns include four columns, and wherein two ends of each truss are each provided with a respective column of the four columns.

19. The data center according to claim 18, wherein the baseplate assembly further comprises a plurality of lower short beams, wherein two ends of each lower short beam are respectively connected to the two trusses.

20. The data center according to claim 17, wherein the baseplate assembly further comprises a plurality of lower short beams, wherein two ends of each lower short beam are respectively connected to the two trusses.
